(19) United States
(12) Patent Application Publication
(10) Pub. No.: US 2013/0133931 A1
(43) Pub. Date: May 30, 2013

(54) PRINTED WIRING BOARD

(71) Applicant: FUJIKURA LTD., Tokyo (JP)

(72) Inventors: Hirohito WATANABE, Sakura-shi (JP); Akiko OGAWA, Tokyo (JP)

(73) Assignee: FUJIKURA LTD., Tokyo (JP)

(21) Appl. No.: 13/686,597

(22) Filed: Nov. 27, 2012

(30) Foreign Application Priority Data
Nov. 28, 2011 (JP) 2011-258921

(51) Int. Cl. H05K 1/02

(52) U.S. Cl. CPC H05K 1/02
USPC 174/254

(57) ABSTRACT

Provided is a printed wiring board capable of inhibiting a reinforcing plate from peeling off even when a bending radius is small. The printed wiring board includes a wiring board main body, and a reinforcing plate attached to the wiring board main body, the reinforcing plate includes first and second reinforcing portions which are arranged to be mutually spaced apart, and a connecting portion which integrally connects the first reinforcing portion with the second reinforcing portion, and the connecting portion includes a first portion which has a cross-sectional area smaller than a cross-sectional area of the first reinforcing portion and smaller than a cross-sectional area of the second reinforcing portion, and a second portion of which a cross-sectional area increases along a direction from the first portion to at least one of the first reinforcing portion and the second reinforcing portion.

### BACKGROUND OF THE INVENTION

1. Field of the Invention

The present invention relates to a printed wiring board that includes a reinforcing plate and is to be bent with a small bending radius.

This application is based upon and claims the benefit of priority from Japanese Patent Application No. 2011-258921, filed on Nov. 28, 2011; the entire contents of which are incorporated herein by reference.

2. Description of the Related Art

There is a known flexible printed circuit (FPC) including an FPC main body and a reinforcing plate attached to a portion on a tray side of a flexure of the FPC main body through an adhesive sheet (see, for example, JP 2010-239109 A). In the FPC, the rigidity of the FPC is ensured through the reinforcing plate, thereby inhibiting the FPC from being corrugated due to a movement of the tray.

The above-mentioned reinforcing plate includes an end portion on the flexure side. When the bending radius of the FPC is small, there is a problem in that a stress is concentrated on the end portion due to the flexures of the FPC main body, and the reinforcing plate peels off the FPC main body.

A subject to be solved by the invention is to provide a printed wiring board capable of inhibiting the reinforcing plate from peeling off even when the bending radius is small.

### SUMMARY OF THE INVENTION

[1] A printed wiring board according to the invention includes a wiring board main body, and a reinforcing plate which is attached to the wiring board main body, wherein the reinforcing plate includes first and second reinforcing portions which are arranged to be mutually spaced apart, and a connecting portion which integrally connects the first reinforcing portion with the second reinforcing portion, and the connecting portion includes a first portion which has a cross-sectional area smaller than a cross-sectional area of the first reinforcing portion and smaller than a cross-sectional area of the second reinforcing portion, and a second portion of which a cross-sectional area increases along a direction from the first portion to at least one of the first reinforcing portion and the second reinforcing portion.

[2] In the above invention, the wiring board main body may include a bending subject portion which is to be bent about a bending line, and the connecting portion may correspond to the bending subject portion.

[3] In the above invention, an outside width of the bending subject portion may be substantially equal to an outside width of the connecting portion.

[4] In the above invention, an opening may be formed in the connecting portion, and a rim of the opening may have an arc shape in a portion near at least one of the first reinforcing portion and the second reinforcing portion in a planar view.

[5] In the above invention, the printed wiring board may be bent in the bending subject portion.

According to the invention, it is possible to inhibit the reinforcing plate from peeling off the wiring board main body, since a connecting portion integrally connects the first reinforcing portion with the second reinforcing portion.

Further, in the invention, the connecting portion includes the first portion which has the cross-sectional area smaller than the cross-sectional area of the first reinforcing portion and smaller than the cross-sectional area of the second reinforcing portion and thus, it is possible to weaken the rigidity of the reinforcing plate in the connecting portion, and deal with a small bending radius.

Further, in the invention, the connecting portion includes the second portion where the cross-sectional area increases along a direction from the first portion to at least one of first and second reinforcing portions, and thus it is possible to relieve a local stress concentration, and further inhibit the reinforcing plate from peeling off even when a bending radius is small.

### BRIEF DESCRIPTION OF THE DRAWINGS

FIG. 1 is a plane view illustrating a printed wiring board in an embodiment of the invention.

FIG. 2A is a bottom view of the printed wiring board illustrated in FIG. 1, and FIG. 2B is a graph illustrating a change in a cross-sectional area of a reinforcing plate illustrated in FIG. 2A.

FIG. 3 is a cross-sectional view taken along line III-III of FIGS. 1 and 2A.

FIG. 4 is a cross-sectional view taken along line IV-IV of FIGS. 1 and 2A.

FIG. 5 is a cross-sectional view taken along line V-V of FIGS. 1 and 2A.

FIG. 6 is a cross-sectional view taken along line VI-VI of FIGS. 1 and 2A.

FIG. 7A is a bottom view illustrating a first modified example of the reinforcing plate in an embodiment of the invention, and FIG. 7B is a graph illustrating a change in a cross-sectional area of the reinforcing plate illustrated in FIG. 7A.

FIG. 8A is a bottom view illustrating a second modified example of the reinforcing plate in an embodiment of the invention, and FIG. 8B is a graph illustrating a change in a cross-sectional area of the reinforcing plate illustrated in FIG. 8A.

FIG. 9A is a bottom view illustrating a third modified example of the reinforcing plate in an embodiment of the invention, and FIG. 9B is a graph illustrating a change in a cross-sectional area of the reinforcing plate illustrated in FIG. 9A.

FIG. 10A is a bottom view illustrating a fourth modified example of the reinforcing plate in an embodiment of the invention, and FIG. 10B is a graph illustrating a change in a cross-sectional area of the reinforcing plate illustrated in FIG. 10A.

FIG. 11A is a bottom view illustrating a fifth modified example of the reinforcing plate in an embodiment of the invention, and FIG. 11B is a graph illustrating a change in a cross-sectional area of the reinforcing plate illustrated in FIG. 11A.

FIG. 12A is a bottom view illustrating a sixth modified example of the reinforcing plate in an embodiment of the invention, and FIG. 12B is a graph illustrating a change in a cross-sectional area of the reinforcing plate illustrated in FIG. 12A.

FIG. 13A is a bottom view of a printed wiring plate of Comparative Example 1, and FIG. 13B is a bottom view of a printed wiring plate of Comparative Example 2.

### DETAILED DESCRIPTION OF THE PREFERRED EMBODIMENTS

Hereinafter, embodiments of the invention will be described with reference to the drawings.

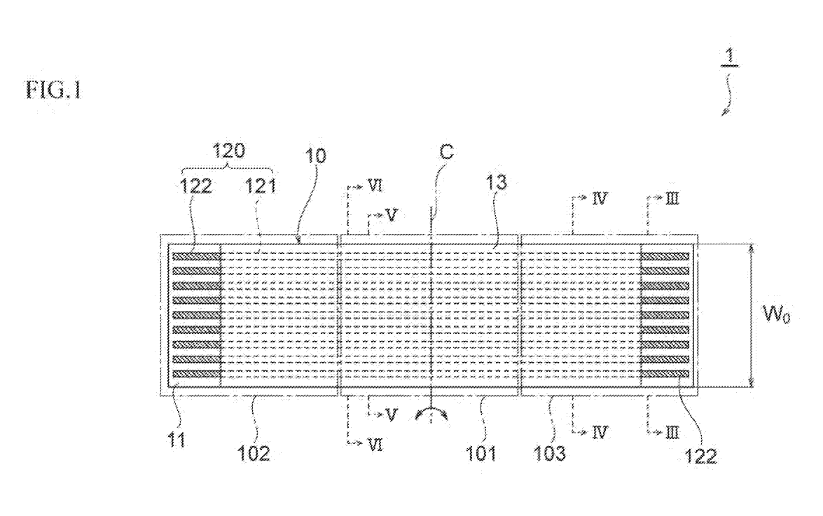

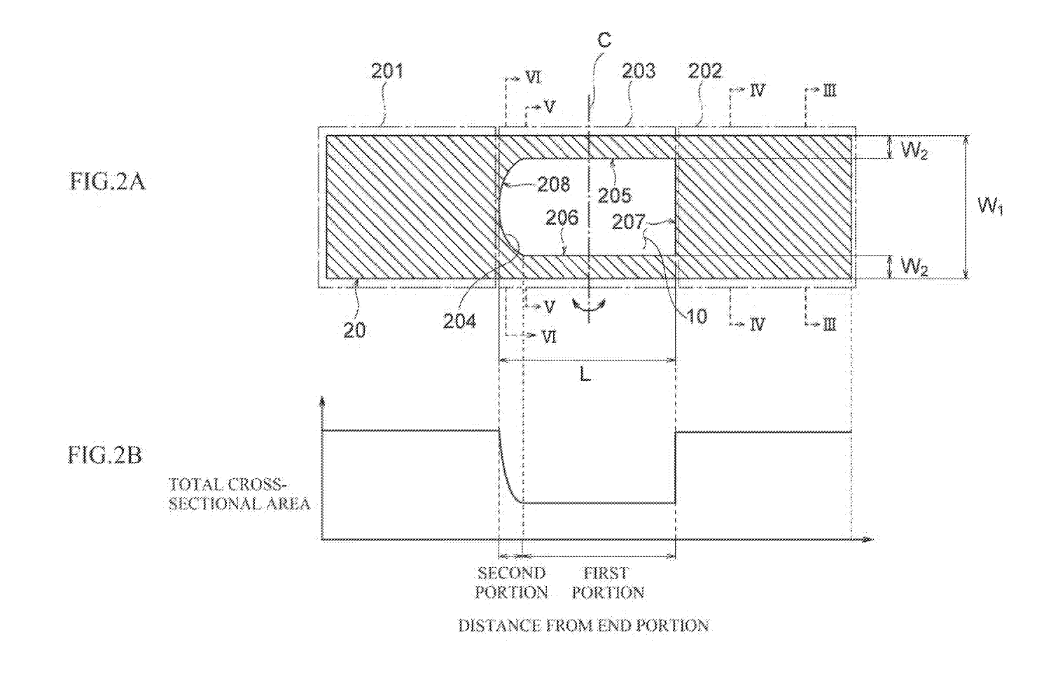

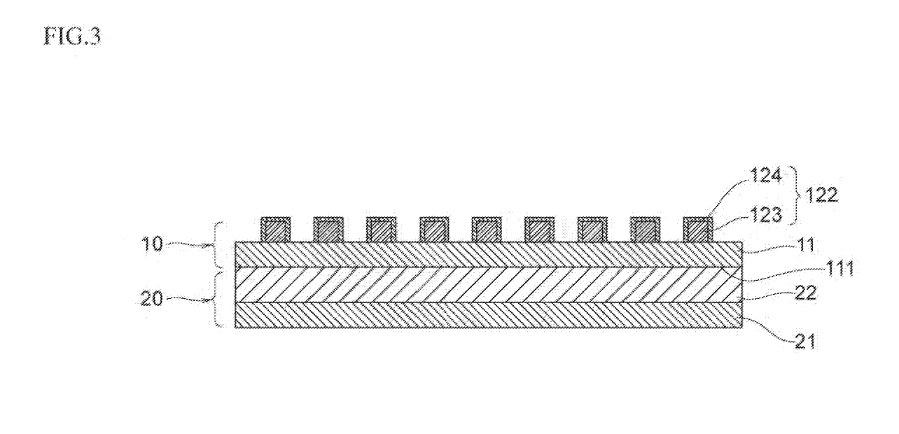

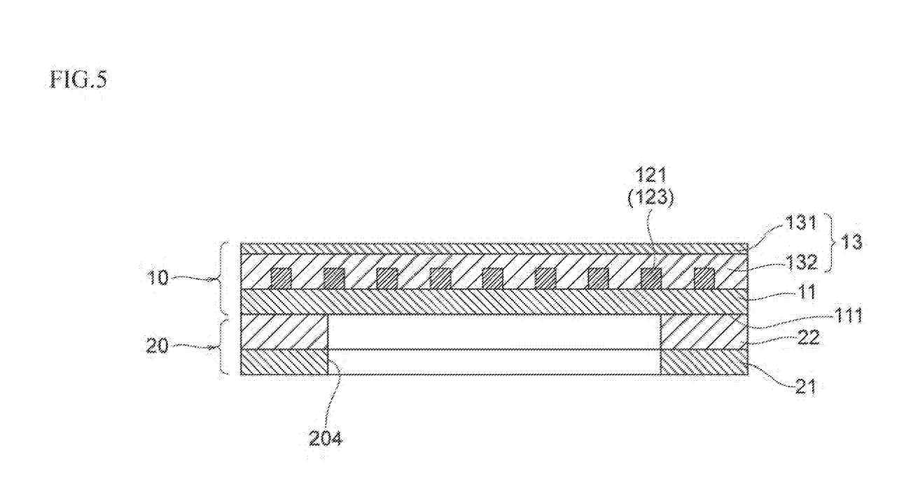

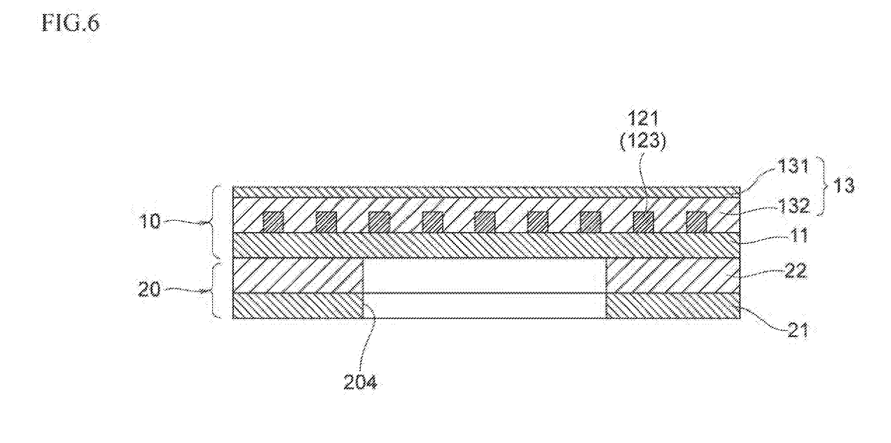

FIGS. 1 and 2A are a plane view and a bottom view illustrating a printed wiring board in an embodiment of the invention, FIG. 2B is a graph illustrating a change in a cross-sectional area of the reinforcing plate illustrated in FIG. 2A, FIG. 3 is a cross-sectional view taken along line III-III of FIGS. 1 and 2A, FIG. 4 is a cross-sectional view taken along line IV-IV of FIGS. 1 and 2A, FIG. 5 is a cross-sectional view taken along line V-V of FIGS. 1 and 2A, and FIG. 6 is a cross-sectional view taken along line VI-VI of FIGS. 1 and 2A.

A printed wiring board 1 in the embodiment is, for example, a flexible printed circuit board (FPC) incorporated in an electronic device such as a mobile phone, a personal digital assistant (PDA), a smart phone, a notebook computer, tablet information terminal, a digital camera, a digital video camera, a digital audio player, a hard disk, and the like.

As illustrated in FIGS. 1 to 6, the printed wiring board 1 includes a wiring board main body 10 and a reinforcing plate 20 attached to the wiring board main body 10, and has a strip shape when viewed as a whole. Moreover, a planar shape of the printed wiring board is not particularly limited, and may be arbitrary selected.

The wiring board main body 10 includes a base film 11, wiring patterns 12, and a coverlay 13.

The base film 11 is, for example, a flexible insulating film composed of polyimide (PI). Here, the base film 11 may be composed of, for example, liquid crystal polymer (LCP), polyethylene terephthalate (PET), polyethylene naphthalate (PEN), polyester (PE), aramid, or the like.

A plurality of wiring patterns 12 are formed on the base film 11. In the embodiment, as illustrated in FIG. 1, the plurality of wiring patterns 12 are arranged parallel to one another at equal intervals, and is linearly extended on the base film 11. Here, a shape, an arrangement, and the like of the wiring patterns 12 are not particularly limited thereto. Further, the wiring patterns may be formed on both surfaces of the base film 11, and a via-hole and the like may be included in the wiring patterns.

Terminals 122 are formed at both ends of the wiring patterns 12 respectively. The terminals 122 are connected to a connector provided in, for example, another printed wiring board, a cable, or the like, and the printed wiring board 1 is electrically connected to an external electronic circuit through the terminals 122. Here, a position where the terminals are formed is not limited to an end portion of the wiring patterns, and an arbitrary position in the wiring patterns may be selected. Further, the number of the terminals in the wiring patterns is not particularly limited, and the terminals are not necessarily provided in the wiring patterns.

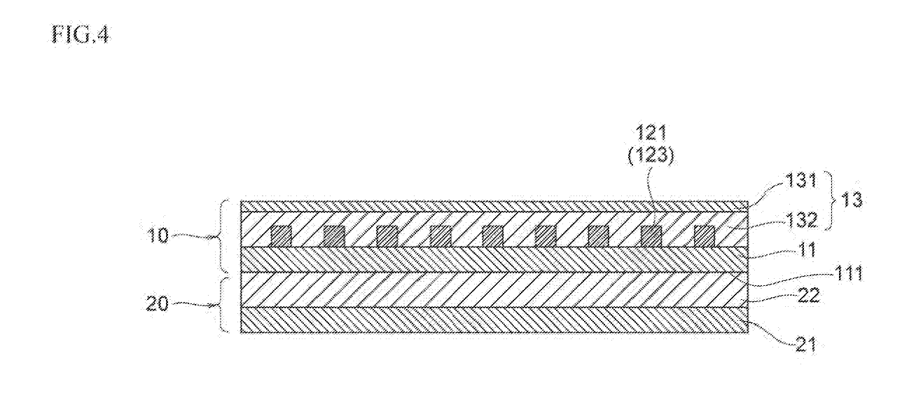

A portion 121 (hereinafter, simply referred to as a wiring portion 121) other than the terminals 122 in the wiring patterns 12 is formed, for example, by etching a copper foil layered on the base film 11 in a predetermined shape, and is formed only from a copper foil 123 as illustrated in FIGS. 4 to 6.

On the other hand, as illustrated in FIG. 3, the terminals 122 of the wiring patterns 12 includes the copper foil 123 extended from the wiring portion 121 and a plated layer 124 formed on the copper foil 123 by an electroplating process or the like. Although not particularly illustrated, the plated layer 124 has, for example, a nickel (Ni) layer as a base and a gold (Au) layer formed on the Ni layer.

The coverlay 13 includes a resin layer 131 for protecting the wiring portion 121 of the wiring patterns 12 and an adhesion layer 132 that bonds the resin layer 131 to the base film 11 as illustrated in FIGS. 4 to 6, and is layered on the base film 11 so as to cover the wiring portion 121 of the wiring patterns 12 as illustrated in FIG. 1. On the other hand, as illustrated in the same drawing, the terminals 122 of the wiring patterns 12 are exposed from the coverlay 13.

The resin layer 131 of the coverlay 13 is, for example, a flexible insulating base material composed of PI. Here, the resin layer 131 may be composed of, for example, LCP, PET, PEN, PE, aramid, or the like.

On the other hand, the adhesion layer 132 of the coverlay 13 is formed from, for example, an epoxy adhesive or an acrylic adhesive. Here, when the base film 11 is composed of LCP and the resin layer 131 of the coverlay 13 is also composed of LCP, the base film and the resin layer may be attached to each other through a thermal fusion bonding and thus, the adhesive layer 132 is unnecessary.

Here, the coverlay 13 may be formed from a dry film composed of a photosensitive coverlay material using, for example, polyester, epoxy, acryl, polyimide, polyurethane, and the like. Alternatively, the coverlay 13 may be formed by screen-printing on the base film 11, a coverlay ink using polyimide or epoxy as a base, or a liquid photosensitive coverlay material.

As illustrated in FIG. 1, the above-described wiring board main body 10 is incorporated in an electronic device in a state of being bent with a bending radius equal to or less than 0.3 mm about a folding line C, for example. Furthermore, the printed wiring board 1 of the embodiment is permanently incorporated in an electronic device in a state of being bent (plastic-deformed) with an infinitesimal bending radius rather than being incorporated in a movable portion of an electronic device including repeated flexures. Thus, the printed wiring board 1 of the embodiment is required to have toughness for the infinitesimal bending radius rather than bend durability. Moreover, the above-mentioned bending position or bending radius of the printed wiring board is merely an example, and it is not particularly limited thereto.

In the embodiment, as illustrated in FIGS. 2 to 6, the reinforcing plate 20 is attached to a lower surface 111 (a surface opposite to a surface where the wiring patterns 12 are formed in the base film 11) of the base film 11. The reinforcing plate 20 includes a base material 21 reinforcing the wiring board main body 10 and an adhesion layer 22 bonding the base material 21 to the base film 11.

The base material 21 is a plate-like member composed of, for example, a resin material such as PI, LCP, PET, PEN, glass epoxy, aramid, or the like, or a metal material such as stainless steel, aluminum, aluminum alloy, or the like.

On the other hand, the adhesion layer 22 is composed of, for example, epoxy based or acryl based thermosetting resin. Moreover, the adhesion layer 22 may be formed from a tackifier.

Here, as illustrated in FIG. 1, the wiring board main body 10 includes a bending subject portion 101 that is to be bent about the folding line C, and first and second adjacent portions 102 and 103 positioned on both sides of the bending subject portion 101. As illustrated in FIG. 2A, in the embodiment, to correspond to this, the reinforcing plate 20 includes a first reinforcing portion 201, a second reinforcing portion 202, and a connecting portion 203.

The first reinforcing portion 201 is attached to the first adjacent portion 102 of the wiring board main body 10, and the second reinforcing portion 202 is attached to the second adjacent portion 103 of the wiring board main body 10. Further, the connecting portion 203 is attached to the bending subject portion 101 of the wiring board main body 10, and integrally connects the first and second reinforcing portions 201 and 202 with each other.

As described above, in the embodiment, the reinforcing plate 20 is also attached to the bending subject portion 101 of the wiring board main body 10. Accordingly, when the printed wiring board 1 is bent, the bending radius is uniform due to the rigidity of the reinforcing plate 20 and thus, the reinforcing plate 20 is inhibited from peeling off the wiring board main body 10 due to the flexures.

Here, the bending line C is a virtual straight line. Further, the bending subject portion 101 is a portion expected to be bent about the bending line C in the wiring board main body 10, and is a region including the bending line C and a vicinity of the bending line C in the wiring board main body 10. On the other hand, the first and second adjacent portions 102 and 103 are unexpected to be bent, and are portions where, for example, a connector is connected or an electronic component is mounted and thus, are required to have a certain degree of rigidity.

In the embodiment, as illustrated in FIGS. 1 and 2A, an outside width W₀ of the bending subject portion 101 of the wiring board main body 10 is substantially equal to an outside width W₁ of the connecting portion 203 of the reinforcing plate 20 (W₀=W₁). Thus, since the reinforcing plate 20 is fixed to the wiring board main body 10 at both ends in a width direction in the bending subject portion 101, the reinforcing plate 20 is difficult to peel off when the printed wiring board 1 is bent.

Here, the terms “outside width” and “width” in the embodiment refer to a length in a direction along the bending line C.

Further, as illustrated in FIGS. 2A, 5, and 6, an opening 204 is formed in the connecting portion 203 of the reinforcing plate 20. Thus, as illustrated in FIG. 2B, the connecting portion 203 of the embodiment includes a first portion which has a cross-sectional area smaller than a cross-sectional area of the first reinforcing portion 201 and smaller than a cross-sectional area of the second reinforcing portion 202. Thus, it is possible to weaken the rigidity of the reinforcing plate 20 in the connecting portion 203, and deal with a small bending radius.

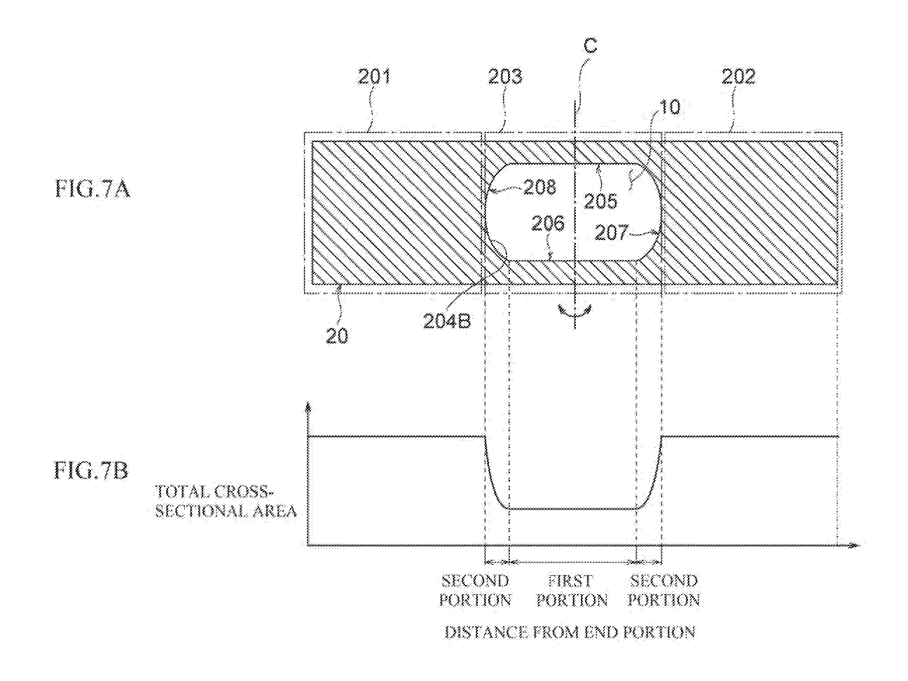

Here, FIG. 2B illustrates a relation between a cross-sectional area of the reinforcing plate illustrated in FIG. 2A and a distance from a left end portion of the reinforcing plate of FIG. 2A in a longitudinal direction of the printed wiring board, which is similarly applied to FIGS. 7 to 12 described below.

Further, the term “cross-sectional area” in the embodiment refers to an area of a cross-sectional surface taken along the bending line C, and the term “cross-sectional area of the connecting portion 203” in the embodiment refers to a sum of areas of respective cross-sectional surface taken along the bending line C.

As illustrated in FIG. 2A, the opening 204 in the embodiment is formed from a pair of long sides 205 and 206 and a pair of short sides 207 and 208. Here, a length relation between the sides 205 and 206 and the sides 207 and 208 is determined based on the outside width W₁ of the reinforcing plate 20, a length L of the connecting portion 203 and the like, and it is not particularly limited to the above-described relation.

The pair of long sides 205 and 206 faces each other along a direction (a width direction of the printed wiring board 1) substantially parallel to the bending line C, and both of the first and second long sides 205 and 206 are formed in a straight line.

On the other hand, the pair of short sides 207 and 208 faces each other along a direction (a longitudinal direction of the printed wiring board 1) substantially perpendicular to the bending line C. While the first short side 207 is formed in a straight line, the second short side 208 is formed in an arc. The entire second short side 208 forms a convex arc shape toward the first reinforcing portion 201.

That is, in the embodiment, a rim of the opening 204 of the connecting portion 203 includes the second short side 208 in a shape of an arc in a portion near the first reinforcing portion 201. Thus, as illustrated in FIG. 2B, the connecting portion 203 of the embodiment includes a second portion in which a cross-sectional area of the connecting portion 203 continuously increases along a direction from the first portion to the first reinforcing portion 201 (that is, along a direction from the right side to the left side in the drawing). Here, the term “side” in the embodiment includes a curved line in addition to a straight line for the sake of convenience.

In the embodiment, since the connecting portion 203 includes the second portion, a local stress concentration may be relieved, and the reinforcing plate 20 may be further inhibited from peeling off even when the bending radius is small.

Here, a shape of the reinforcing plate 20 is not particularly limited to the above-described shape, and may be a shape illustrated in FIGS. 7A to 12A. FIGS. 7A to 12A are diagrams illustrating modified examples of the reinforcing plate, and FIGS. 7B to 12B are graphs illustrating a change in a cross-sectional area of the reinforcing plate illustrated in FIGS. 7A to 12A.

In the above-described opening 204 (see FIG. 2A), although only the short side 208 close to the first reinforcing portion 201 is formed in an arc, it is not particularly limited thereto. For example, as an opening 204B illustrated in FIG. 7A, in addition to the second short side 208, the first short side 207 close to the second reinforcing portion 202 may be formed in an arc. In this case, as illustrated in FIG. 7B, a cross-sectional area of the connecting portion 203 continuously increases in both ends of the opening 204B.

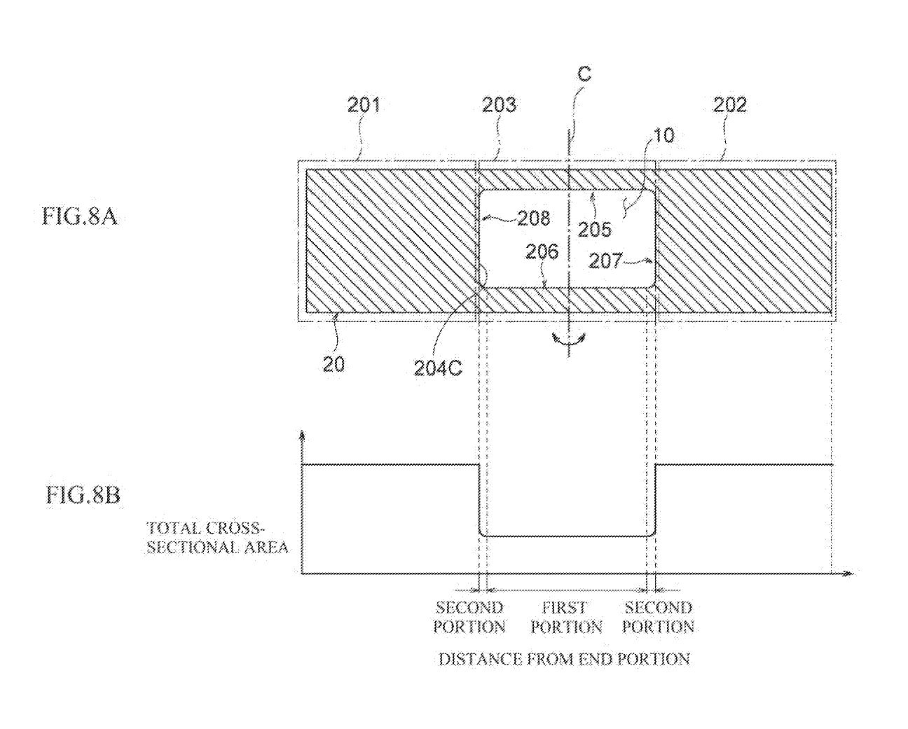

Further, in the above-described opening 204, the entire second short side 208 is formed in an arc shape. However, it is not particularly limited thereto. For example, as an opening 204C illustrated in FIG. 8A, only both ends of the short sides 207 and 208 may be formed in an arc shape, and a central portion of the short sides 207 and 208 may be formed in a straight line shape. In this case, as illustrated in FIG. 8B, a cross-sectional area of the connecting portion 203 continuously increases in both ends of the opening 204C. Here, both ends of the short side 207 or 208 may not be formed in an arc, and the entire short side 207 or 208 may be formed in a straight line.

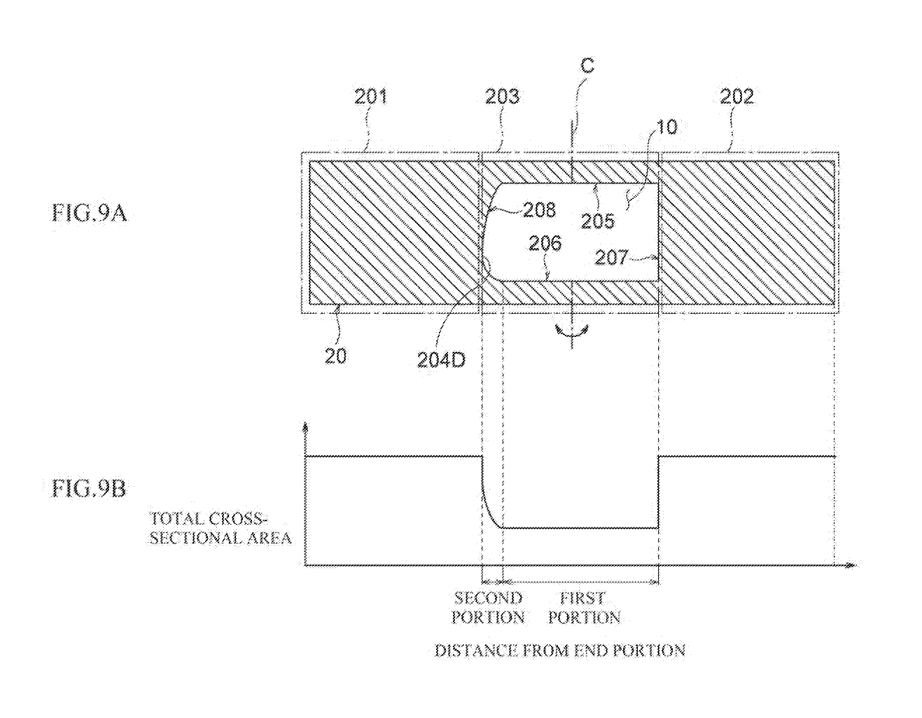

Further, in the opening 204, the arc shape of the second short side 208 forms a line symmetry about a direction (a longitudinal direction of the printed wring board 1) substantially perpendicular to the bending line C. However, it is not particularly limited thereto. For example, as an opening 204D illustrated in FIG. 9A, the second short side 208 may be asymmetric about the longitudinal direction of the printed wring board. In this case, as illustrated in FIG. 9B, a cross-sectional area of the connecting portion 203 continuously increases in a left end of the opening 204D. Here, in addition to the second short side 208, the first short side 207 may have an asymmetric arc shape.

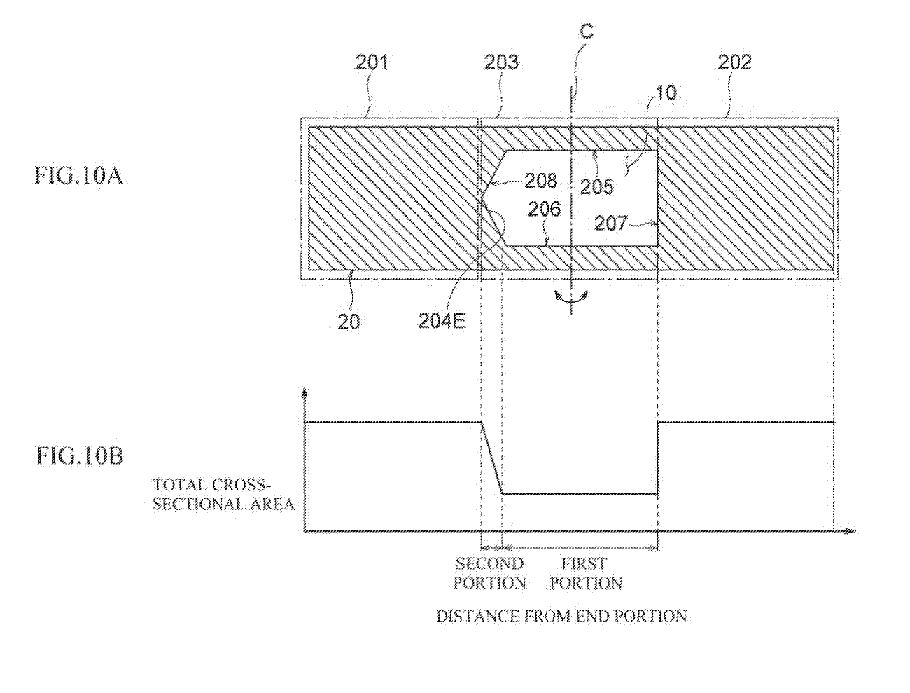

Further, in the above-described opening 204, the second short side 208 is formed in an arc shape to continuously increase the cross-sectional area of the connecting portion 203. However, it is not particularly limited thereto. For example, as an opening 204E illustrated in FIG. 10A, the second short side 208 may be bent substantially in a V-shape so that the entire shape of the opening 204E forms a substantially pentagonal shape. In this case, as illustrated in FIG. 10B, a cross-sectional area of the connecting portion 203 continuously increases in a left end of the opening 204E. Here, it is preferable that a slight curvature is given to a corner portion of the opening 204E. Further, in addition to the second short side 208, the first short side 207 may have a shape bent substantially in a V-shape.

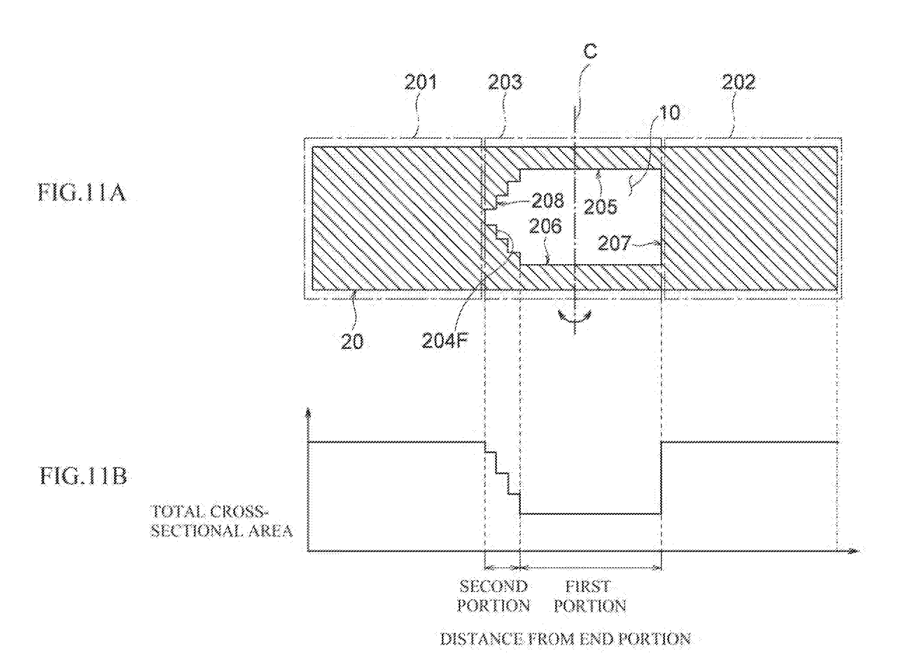

Alternatively, as an opening 204F illustrated in FIG. 11A, the second short side 208 may have a shape bent in a multistep shape. In this case, as illustrated in FIG. 11B, a cross-sectional area of the connecting portion 203 increases in a stepwise manner in a left end of the opening 204F. Here, it is preferable that a slight curvature is given to a corner portion of the opening 204F. Further, in addition to the second short side 208, the first short side 207 may have a shape bent in a multistep shape.

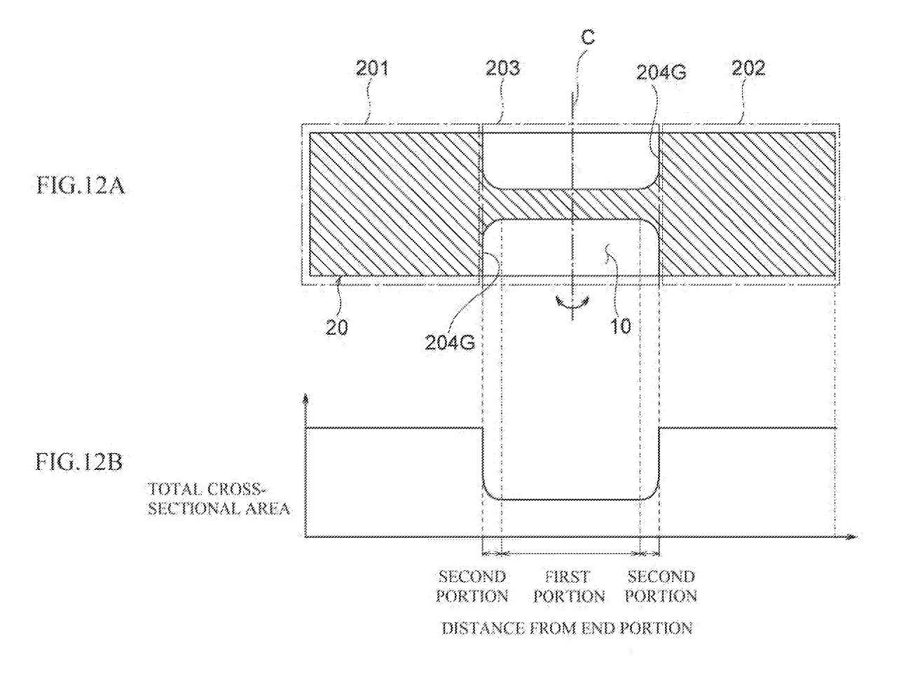

Further, as illustrated in FIG. 12A, a cutout 204G may be formed in the connecting portion 203 instead of the opening 204. In an example illustrated in FIG. 12A, both sides of the connecting portion 203 are cut out in an arc shape by a pair of cutouts 204G. As illustrated in FIG. 12B, a cross-sectional area of the connecting portion 203 continuously increases along a direction toward the first and second reinforcing portions 201 and 202.

As described above, in the embodiment, the connecting portion 203 integrally connects the first reinforcing portion 201 with the second reinforcing portion 202. Thus, it is possible to inhibit the reinforcing plate 20 from peeling off the wiring board main body 10 when the printed wiring board 1 is bent.

Further, in the embodiment, as illustrated in FIG. 2B and FIGS. 7B to 12B, the connecting portion 203 includes the first portion which has a cross-sectional area smaller than a cross-sectional area of the first reinforcing portion 201 and a cross-sectional area of the second reinforcing portion 202. Thus, it is possible to weaken the rigidity of the reinforcing plate 20 in the connecting portion 203, and deal with a small bending radius.

Moreover, in the embodiment, the connecting portion 203 includes the second portion in which a cross-sectional area increases gradually or in a stepwise manner along a direction from the first portion to the first reinforcing portion 201 and the second reinforcing portion 202. Accordingly, it is possible to relieve a local stress concentration, and further inhibit the reinforcing plate 20 from peeling off even when the bending radius is small.

Here, the embodiment descried in the above is described to facilitate understanding of the invention, and is not described to limit the invention. Accordingly, each component described in the embodiment includes all design changes and equivalents belonging to a technical scope of the invention.

### EXAMPLES

Hereinafter, an effect of the invention is verified through Examples and Comparative Examples further specifically describing the invention. Examples and Comparative Examples below are provided to verify the effect of inhibiting the reinforcing plate from peeling off in the above-described embodiment.

### Example 1

In Example 1, ten strip-shaped printed wiring boards illustrated in FIGS. 1 and 2A described in the embodiment are manufactured as samples.

In particular, first, a strip-shaped single sided CCL (copper clad laminate) in which a copper foil having a thickness of 18 μm is layered on a polyimide film (base film) having a thickness of 25 μm with an adhesive having a thickness of 10 μm interposed therebetween is prepared. Subsequently, a resist pattern is formed on the copper foil, and then an etching process is performed on the copper foil, thereby forming a plurality of linear wiring patterns having a width of 40 μm so as to be parallel to each other at a pitch 80 μm.

Subsequently, a coverlay in which a thermosetting adhesive having a thickness of 30 μm is applied to a polyimide film having a thickness of 12 μm is layered on the base film so that each of both ends of the wiring patterns is exposed.

Subsequently, a polyimide film having a thickness of 25 μm is layered on a lower surface of the base film with a thermosetting adhesive having a thickness of 30 μm interposed therebetween, and a curing treatment is performed using a hot press, thereby bonding the coverlay, the base film, and the reinforcing plate together.

In Example 1, an outside width W₀ of a bending subject portion of a wiring board main body is set to 5 mm, and an outside width W₁ of a connecting portion of the reinforcing plate is also set to 5 mm. Further, a distance L (that is, a length of the connecting portion) between a first reinforcing portion and a second reinforcing portion in the reinforcing plate is set to 3 mm, and a width W₂ of the connecting portion of the reinforcing plate is set to 1 mm.

Moreover, in Example 1, an opening of the reinforcing plate is formed in a shape illustrated in FIG. 2A. In particular, a central portion of a second short side of the opening is formed in an arc having a radius of 3 mm, and both end portions of the second short side are formed in an arc having a radius of 0.3 mm.

Ten printed wiring boards manufactured as described above are manually bent about a bending line (corresponding to a symbol C in FIGS. 1 and 2A) using a mandrel having a diameter of 0.6 mm (bending radius: 0.3 mm) and are plastic-deformed. Thereafter, whether the reinforcing plate peels off is verified through a visual observation using a microscope.

In Example 1, as illustrated in Table 1, peeling off of the reinforcing plate does not occur in all samples. Here, in the “result” section of Table 1, a symbol “1” denotes a case in which peeling off of the reinforcing plate does not occur in ten samples, a symbol “2” denotes a case in which peeling off of the reinforcing plate occurs in three or less samples out of ten samples, and a symbol “3” denotes a case in which peeling off of the reinforcing plate occurs in four or more samples out of ten samples.

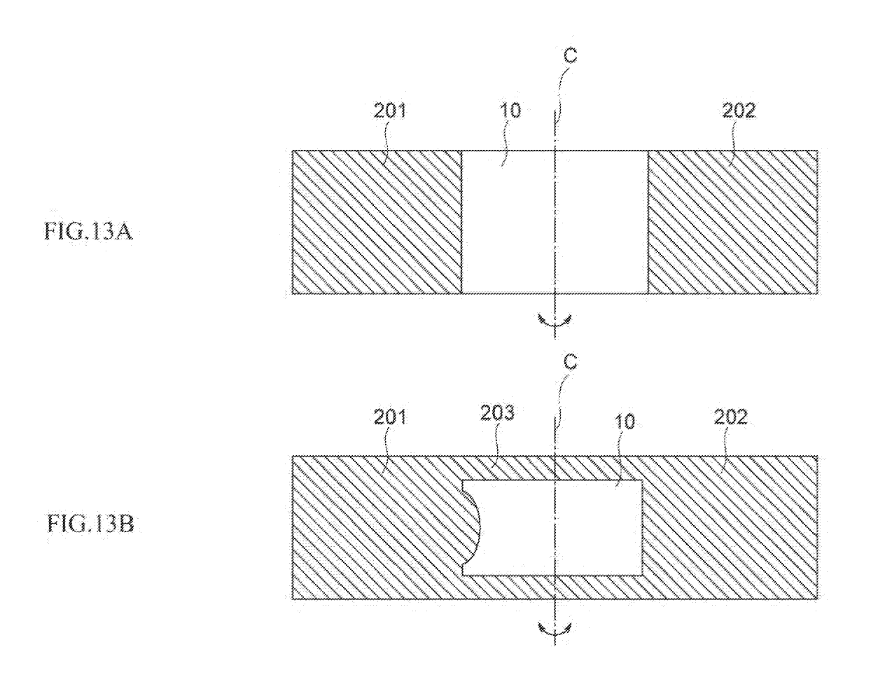

TABLE 1

| | configuration | result |
|---|---|---|
| Example 1 | configuration of Fig. 2 | 1 |
| Example 2 | configuration of Fig. 8 | 2 |
| Comparative Example 1 | configuration of Fig. 13A | 3 |
| Comparative Example 2 | configuration of Fig. 13B | 3 |

### Example 2

In Example 2, except that a shape of an opening of a reinforcing plate is formed in a shape of FIG. 8A, ten samples similar to those of Example 1 are manufactured. In Example 2, both end portions of first and second short sides of the opening are formed in an arc having a radius of 0.2 mm.

For the samples of Example 2, under similar conditions to those in Example 1, ten printed wiring boards are bent about a bending line (corresponding to a symbol C in FIG. 8A) and are plastic-deformed. Thereafter, whether the reinforcing plate peels off is verified.

As illustrated in Table 1, in Example 2, peeling off of the reinforcing plate occurs in three samples out of ten samples. However, peeling off of the reinforcing plate does not occur in seven samples.

### Comparative Example 1

In Comparative Example 1, as illustrated in FIG. 13A, except that a connecting portion is not formed on a reinforcing plate, ten samples similar to those of Example 1 are manufactured. FIG. 13A is a bottom view of a printed wiring plate of Comparative Example 1.

For the samples of Comparative Example 1, under similar conditions to those in Example 1, ten printed wiring boards are bent about a bending line (corresponding to a symbol C in FIG. 13A) and are plastic-deformed. Thereafter, whether the reinforcing plate peels off is verified.

As illustrated in Table 1, in Comparative Example 1, peeling off of the reinforcing plate occurs in eight samples out of ten samples.

### Comparative Example 2

In Comparative Example 2, as illustrated in FIG. 13B, except that a first reinforcing portion protrudes toward a connecting portion thereby forming a second short side of an opening in a convex arc shape toward the connecting portion, ten samples similar to those of Example 1 are manufactured. In Comparative Example 2, the second short side of the opening is formed in an arc having a radius of 3 mm. FIG. 13B is a bottom view of a printed wiring board of Comparative Example 2.

For the samples of Comparative Example 2, under similar conditions to those of Example 1, ten printed wiring boards are bent about a bending line (corresponding to a symbol C in FIG. 13B) and are plastic-deformed. Thereafter, whether the reinforcing plate peels off is verified.

As illustrated in Table 1, in Comparative Example 2, peeling off of the reinforcing plate occurs in five samples out of ten samples.

As described above, in Examples 1 and 2 where a cross-sectional area of the connecting portion of the reinforcing plate is increased along a direction toward the first reinforcing portion and the second reinforcing portion, it is possible to inhibit the reinforcing plate from peeling off due to bending.

On the other hand, in Comparative Example 1 where the connecting portion is not formed on the reinforcing plate, stress concentrates on the end portion of the first reinforcing portion and the end portion of the second reinforcing plate and thus, peeling off of the reinforcing plate occurs. Further, in Comparative Example 2 where the first reinforcing portion protrudes, stress concentrates on the center of the second short side, and thus peeling off of the reinforcement plate occurs.

### EXPLANATION OF REFERENCE NUMERALS

1 . . . printed wiring board
10 . . . wiring board main body
101 . . . bending subject portion
102 . . . first adjacent portion
103 . . . second adjacent portion
11 . . . base film
12 . . . wiring pattern
121 . . . wiring portion
13 . . . coverlay
20 . . . reinforcing plate
201 . . . first reinforcing portion
202 . . . second reinforcing portion
203 . . . connecting portion
204 . . . opening

What is claimed is:

1. A printed wiring board, comprising:
a wiring board main body; and
a reinforcing plate which is attached to the wiring board main body,
wherein the reinforcing plate includes:
first and second reinforcing portions which are arranged to be mutually spaced apart; and
a connecting portion which integrally connects the first reinforcing portion with the second reinforcing portion, and
the connecting portion includes:
a first portion which has a cross-sectional area smaller than a cross-sectional area of the first reinforcing portion and smaller than a cross-sectional area of the second reinforcing portion, and
a second portion of which a cross-sectional area increases along a direction from the first portion to at least one of the first reinforcing portion and the second reinforcing portion.

2. The printed wiring board according to claim 1,
wherein the wiring board main body includes a bending subject portion which is to be bent about a bending line, and
the connecting portion corresponds to the bending subject portion.

3. The printed wiring board according to claim 2, wherein an outside width of the bending subject portion is substantially equal to an outside width of the connecting portion.

4. The printed wiring board according to claim 3,
wherein an opening is formed in the connecting portion, and
a rim of the opening has an arc shape in a portion near at least one of the first reinforcing portion and the second reinforcing portion in a planar view.

5. The printed wiring board according to claim 2 wherein the printed wiring board is bent in the bending subject portion.
